(19) United States
(12) Patent Application Publication
(10) Pub. No.: US 2018/0372812 A1
(43) Pub. Date: Dec. 27, 2018

(54) EQUILIBRIUM-TYPE MAGNETIC FIELD DETECTION DEVICE

(71) Applicant: Alps Electric Co., Ltd., Tokyo (JP)

(72) Inventors: Hideaki KAWASAKI, Miyagi-ken (JP); Akira TAKAHASHI, Miyagi-ken (JP)

(21) Appl. No.: 16/118,129

(22) Filed: Aug. 30, 2018

Related U.S. Application Data
(63) Continuation of application No. PCT/JP2017/004692, filed on Feb. 9, 2017.

(30) Foreign Application Priority Data
Mar. 30, 2016 (JP) 2016-067448

(51) Int. Cl. G01R 33/09; G01R 15/20; H01L 43/08; G01R 33/00

(52) U.S. Cl. CPC G01R 33/09; G01R 15/205; G01R 33/0041; H01L 43/08; G01R 15/207

(57) ABSTRACT

An equilibrium-type magnetic field detection device is provided with a magnetism detection unit that detects a magnetic field under measurement. According to a detection output from the magnetism detection unit, a cancel current is supplied to a feedback coil and a cancel magnetic field is supplied to the magnetism detection unit. The detection output is a coil current at a time when the magnetic field under measurement and the cancel magnetic field are placed in an equilibrium state. Since a plurality of magnetoresistance effect elements oppose a single coil conductor, it is possible to improve the linearity of detection outputs, reduce hysteresis, and increase detection sensitivity.

### CLAIM OF PRIORITY

This application is a Continuation of International Application No. PCT/JP2017/004692 filed on Feb. 9, 2017, which claims benefit of Japanese Patent Application No. 2016-067448 filed on Mar. 30, 2016. The entire contents of each application noted above are hereby incorporated by reference.

### BACKGROUND OF THE INVENTION

### 1. Field of the Invention

The present invention relates to an equilibrium-type magnetic field detection device that uses a feedback coil.

### 2. Description of the Related Art

An invention related to an equilibrium-type magnetic field detection device that detects the magnitude of a current under measurement is described in International Publication No. WO2013/018665A1.

In this magnetic field detection device, magnetoresistance effect elements and a feedback coil oppose a conductor through which a current under measurement passes. A current-caused magnetic field excited by the current under measurement that flows in the conductor is detected by the magnetoresistance effect elements. Control is performed so that a coil current is supplied to the feedback coil in correspondence to the magnitude of the detection output of the magnetoresistance effect elements. A cancel magnetic field is supplied from the feedback coil to the magnetoresistance effect elements in a direction opposite to the direction of the current-caused magnetic field. When the cancel magnetic field and the current-caused magnetic field detected by the magnetoresistance effect elements are placed in an equilibrium state, a current flowing in the feedback coil is detected. The detection output of the current is the measured value of the current under measurement.

In the magnetic field detection device described in International Publication No. WO2013/018665A1, the magnetoresistance effect elements are formed by connecting a plurality of elongated-strip patterns in parallel to one another so as to form a so-called meandering shape, as illustrated in FIG. 3. The elongated-strip pattern of a single magnetoresistance effect element opposes one of the wiring patterns constituting the feedback coil, as illustrated in FIGS. 5A and 5B.

### SUMMARY OF THE INVENTION

The magnetic field detection device described in International Publication No. WO2013/018665A1 is structured so that the elongated-strip patterns of the magnetoresistance effect elements oppose the wiring patterns of the feedback coil on a one-to-one basis. This causes the following problems.

In the structure in which the elongated-strip patterns of the magnetoresistance effect elements oppose the wiring patterns of the feedback coil on a one-to-one basis, the wiring pitch of the wiring patterns needs to match the wiring pitch of the elongated-strip patterns, so the width of each wiring pattern is of course narrowed. If a cancel magnetic field is induced around each wiring pattern having the narrow width, at the central portion of the elongated-strip patterns in the width direction, the cancel magnetic field is exerted relatively strongly in a horizontal direction, which is a sensitivity-axis direction. At both ends of the elongated-strip patterns in the width direction, however, the cancel magnetic field is likely to be exerted in a direction crossing to the sensitivity axis. As a result, the linearity of the detection outputs of the magnetoresistance effect elements is lowered, and the hysteresis of the detection output becomes large for an alternating magnetic field.

In the structure in which the elongated-strip patterns of the magnetoresistance effect elements oppose the wiring patterns of the feedback coil on a one-to-one basis, a relatively large cancel magnetic field is supplied to one elongated-strip pattern by a current flowing in one wiring pattern. Therefore, even if the magnitude of the current-caused magnetic field is increased or decreased, a range within which the coil current needs to be increased or decreased to cancel the increased or decreased magnetic field cannot be widened. This places a limitation on an extent to which sensitivity to the current-caused magnetic field is increased.

The feedback coil needs to be formed by winding many wiring patterns having a small width. This increases impedance, consuming much electric power.

The equilibrium-type magnetic field detection device of the present invention addresses the above conventional problems by having a plurality of magnetoresistance effect elements oppose to a single coil conductor of a feedback coil.

An equilibrium-type magnetic field detection device according to the present invention includes: a feedback coil formed by winding coil conductors around a flat surface; magnetism detection units, each of which has a plurality of magnetoresistance effect elements, each of which is formed in an elongated-strip shape along the coil conductors; a coil energization unit that supplies, to the coil conductors, a current that induces a magnetic field according to a detection output obtained when the magnetism detection units detect a magnetic field under measurement, the magnetic field being directed so as to cancel the magnetic field under measurement; and a current detection unit that detects the amount of current that flows in the coil conductors. In one magnetism detection unit, the plurality of magnetoresistance effect elements are arranged in parallel and are connected in series. The detection axes of the magnetoresistance effect elements are disposed in the same orientation. A plurality of magnetoresistance effect elements included in one magnetism detection unit oppose a single coil conductor.

In the equilibrium-type magnetic field detection device according to the present invention, the plurality of the magnetoresistance effect elements preferably oppose a portion of the coil conductor, the portion linearly extending.

In the equilibrium-type magnetic field detection device according to the present invention, the coil conductor preferably has a rectangular cross-sectional shape in which the dimension in the height direction is shorter than the dimension in the width direction, the magnetoresistance effect elements opposing the long side of the cross-sectional shape, the long side extending in the width direction of the cross-sectional shape.

In the equilibrium-type magnetic field detection device according to the present invention, it is preferable for the plurality of the magnetoresistance effect elements not to protrude from the relevant coil conductor in the width direction.

In the equilibrium-type magnetic field detection device according to the present invention, a magnetic shield layer is preferably provided that reduces the magnetic field under measurement, which extends to the magnetoresistance effect elements.

In the equilibrium-type magnetic field detection device according to the present invention, a current path is preferably provided. The equilibrium-type magnetic field detection device can be used in a so-called current detection device in which the magnetic field under measurement induced by the current path is supplied to the magnetoresistance effect elements.

In the equilibrium-type magnetic field detection device according to the present invention, a plurality of magnetoresistance effect elements included in a magnetism detection unit oppose a single coil conductor of a feedback coil. Therefore, the width of each coil conductor can be widened. As a result, feedback magnetism can be easily given to each magnetoresistance effect element in a direction along the sensitivity axis, so the linearity of the detection outputs from the magnetism detection units is increased and hysteresis at a time when an alternating current is supplied can be reduced.

Since a feedback magnetic field needed to cancel the magnetic field under measurement is created for the magnetoresistance effect elements, the amount of current flowing in the feedback coil is increased. As a result, coil current can be increased when the magnetic field under measurement is detected, enabling sensitivity to be improved.

Since the width of the coil conductor can be widened and the number of windings of the feedback coil can be reduced, impedance can be lowered and power consumption can also be lowered.

### BRIEF DESCRIPTION OF THE DRAWINGS

FIG. 1 is a plan view illustrating a current detection device that uses an equilibrium-type magnetic field detection device according to an embodiment of the present invention;

FIG. 2 is a plan view illustrating magnetism detection units included in the equilibrium-type magnetic field detection device in FIG. 1 as well as the wiring of these magnetism detection units;

FIG. 3 is a plan view illustrating one magnetism detection unit;

FIG. 4A is a cross-sectional view taken along line IV-IV in FIG. 3, illustrating a feedback coil and shield layer in the equilibrium-type magnetic field detection device according to an embodiment of the present invention, and FIG. 4B is a partially enlarged cross-sectional view;

FIG. 5A is a cross-sectional view of an equilibrium-type magnetic field detection device in a comparative example, the cross-sectional view being equivalent to the cross-sectional view in FIG. 4A, and FIG. 5B is a partially enlarged cross-sectional view;

FIG. 6A is a schematic diagram indicating the strength of a feedback magnetic field at a position at which the magnetism detection unit is placed in the equilibrium-type magnetic field detection device according to the embodiment in FIGS. 4A and 4B, and FIG. 6B is a schematic diagram indicating the strength of a feedback magnetic field at a position at which the magnetism detection unit is placed in the equilibrium-type magnetic field detection device according to the comparative example in FIGS. 5A and 5B;

FIG. 7 is a circuit diagram of the current detection device that uses the equilibrium-type magnetic field detection device;

FIGS. 8A, 8B, and 8C are each a schematic diagram indicating a relationship between the strength of a feedback magnetic field and the width of a coil conductor opposing three magnetoresistance effect elements when the width is changed;

FIGS. 9A, 9B, and 9C are also each a schematic diagram indicating a relationship between the strength of a feedback magnetic field and the width of the coil conductor opposing three magnetoresistance effect elements when the width is changed;

FIGS. 10A, 10B, and 10C each illustrate a structure in which the coil conductor opposing three magnetoresistance effect elements has a different width; and

FIG. 11 illustrates the sensitivity of the equilibrium-type magnetic field detection device according to an embodiment of the present invention.

### DESCRIPTION OF THE PREFERRED EMBODIMENTS

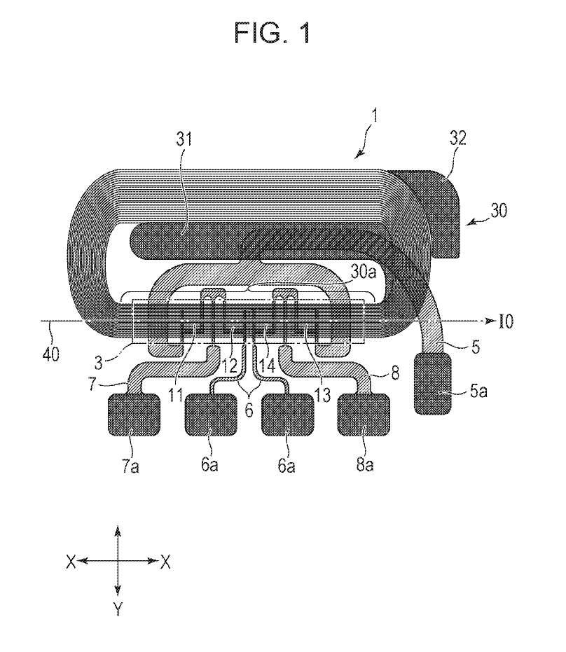

An equilibrium-type magnetic field detection device 1 according an embodiment of the present invention is used as part of a current detection device that detects the amount of a current I0 under measurement that flows in a current path 40 illustrated in FIGS. 1, 2, and 4A. The equilibrium-type magnetic field detection device 1 has magnetism detection units 11, 12, 13, and 14, a feedback coil 30, and a shield layer 3.

In the embodiment of the present invention illustrated in FIGS. 1, 2, and 4A, the current path 40 is placed immediately above the feedback coil 30 and magnetism detection units 11, 12, 13, and 14 in the Z direction. The current path 40 may be placed at a position other than in the embodiment of the present invention if a magnetic field generated by the current I0 under measurement, which flows in the current path 40, can supply a component in the sensitivity-axis direction (Y direction) to the magnetism detection units 11, 12, 13, and 14.

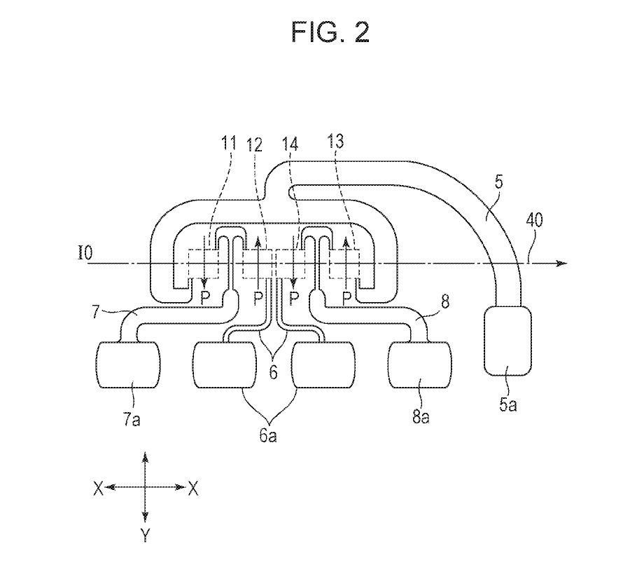

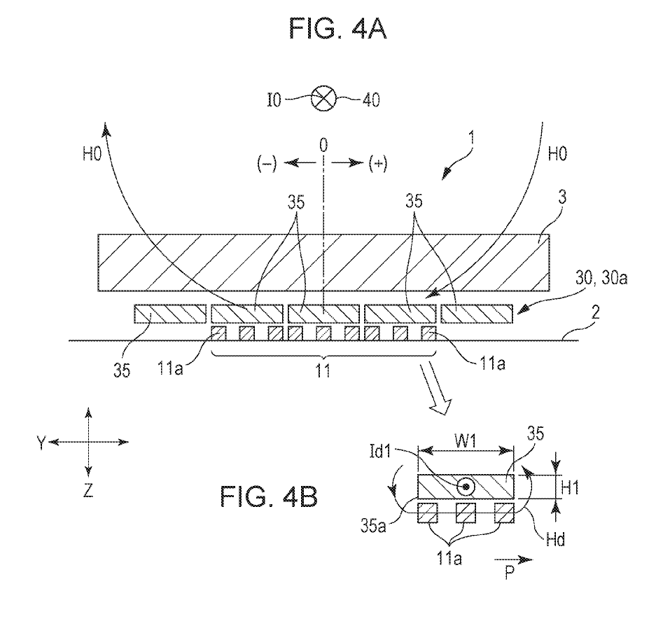

As illustrated in the cross-sectional view in FIG. 4A, the equilibrium-type magnetic field detection device 1 has a substrate 2, which is a silicon (Si) substrate. The surface 2a of the substrate 2 is a flat surface. The magnetism detection units 11, 12, 13, and 14 are formed on the surface 2a. In FIGS. 1 and 2, the magnetism detection units 11, 12, 13, and 14 are illustrated in a plan view. In FIG. 4A, only the magnetism detection unit 11 is illustrated in a cross-sectional view.

As illustrated in FIGS. 1 and 2, the magnetism detection units 11, 12, 13, and 14 are spaced at equal intervals in the X direction. The current path 40 described above extends in the X direction. The current I0 under measurement, which is an alternating current or a direct current, flows in the X direction.

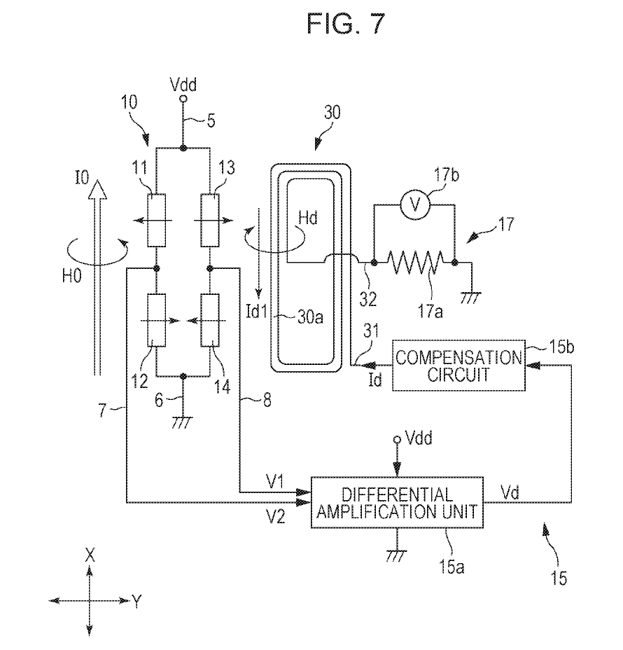

FIGS. 1 and 2 illustrate the placement of the magnetism detection units 11, 12, 13, and 14 and their wiring. FIG. 7 is their circuit diagram. For convenience of explanation, in FIG. 7, the current path 40 is placed to the left of the magnetism detection units 11, 12, 13, and 14 in the Y direction. In the actual equilibrium-type magnetic field detection device 1, however, the current path 40 is placed immediately above the magnetism detection units 11, 12, 13, and 14 in the Z direction as illustrated in, for example, FIGS. 1 and 4A.

A wiring path 5 is connected to the magnetism detection unit 11 positioned at the left end, in FIGS. 1 and 2, of the string of the magnetism detection units 11, 12, 13, and 14 and to the magnetism detection unit 13 positioned at the right end, in these drawings, of the string. A connection land 5a is formed at an end of the wiring path 5. The magnetism detection unit 11 and magnetism detection unit 12 are connected in series, and the magnetism detection unit 13 and magnetism detection unit 14 are connected in series. One wiring path 6 is connected to each of the magnetism detection unit 12 and magnetism detection unit 14 positioned in the central portion of the string. A connection land 6a is formed at an end of each wiring path 6.

A wiring path 7 is connected to an intermediate point between the magnetism detection unit 11 and the magnetism detection unit 12, which are connected in series. A wiring path 8 is connected to an intermediate point between the magnetism detection unit 13 and the magnetism detection unit 14, which are connected in series. A connection land 7a is formed at an end of the wiring path 7. A connection land 8a is formed at an end of the wiring path 8.

The wiring paths 5, 6, 7, and 8 described above are each formed on the surface 2a of the substrate 2 as a conductive layer made of gold, copper, or the like. Each of the connection lands 5a, 6a, 7a, and 8a described above is also formed as a conductive layer made of gold or the like.

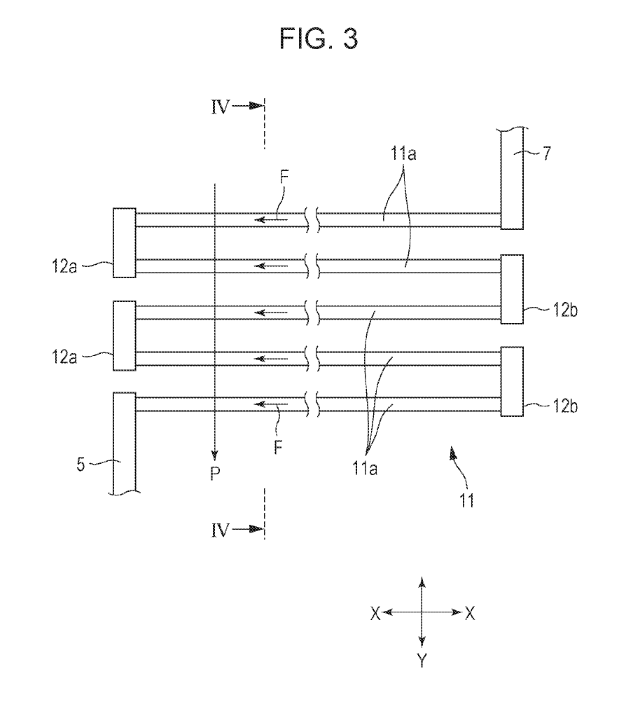

FIG. 3 is an enlarged plan view of the magnetism detection unit 11. The magnetism detection unit 11 is formed from a plurality of magnetoresistance effect elements 11a having a stripe shape (elongated-strip shape) in which the length in the X direction is longer than the width in the Y direction. The plurality of magnetoresistance effect elements 11a in this stripe shape are placed in parallel to one another. Ends of each two adjacent magnetoresistance effect elements 11a at the left side in FIG. 3 are interconnected with a connection electrode 12a. Their ends at the right side in the drawing are interconnected with a connection electrode 12b. That is, the magnetoresistance effect elements 11a are connected like a so-called meandering pattern. In the magnetism detection unit 11, all magnetoresistance effect elements 11a are connected in series. Furthermore, in the magnetism detection unit 11, the magnetoresistance effect element 11a positioned at the upper portion in FIG. 3 is connected to the wiring path 7 and the magnetoresistance effect element 11a positioned at the lower portion in the drawing is connected to the wiring path 5.

The other magnetoresistance effect elements 12, 13, and magnetism detection unit 14 have the same shape in a plan view as the magnetism detection unit 11, in each of which magnetoresistance effect elements 11a in a stripe shape are connected like a so-called meandering pattern with connection electrodes 12a and 12b.

Each magnetoresistance effect element 11a in the magnetism detection units 11, 12, 13, and 14 is a giant magnetoresistance effect element layer (GMR layer) that brings out a giant magnetoresistance effect. Specifically, a fixed magnetic layer, a non-magnetic layer, and a free magnetic layer are sequentially laminated on an insulated substrate layer formed on the surface of the substrate 2. The surface of the free magnetic layer is covered with a protective layer. These layers are formed by chemical vapor deposition (CVD) or in a sputtering process, followed by etching to form a stripe shape. In addition, the wiring paths 5, 6, 7, and 8 and the connection electrodes 12a and 12b, which connect the magnetoresistance effect elements 11a in the stripe shape like a meandering pattern, are formed.

The fixed magnetic layer and free magnetic layer are in a stripe shape in which their longitudinal directions match the X direction. The magnetism of the fixed magnetic layer is fixed in the Y direction. The fixed magnetic layer has a self pinning structure in which a first magnetic layer, a non-magnetic intermediate layer, and a second magnetic layer are laminated. Alternatively, the fixed magnetic layer may have a structure in which a fixed magnetic layer is laminated on an antiferromagnetic layer and the magnetism of the fixed magnetic layer is fixed by an antiferromagnetic coupling between the fixed magnetic layer and the antiferromagnetic layer.

The fixing direction P of the magnetism of the fixed magnetic layer is indicated by an arrow in FIGS. 2 and 3. The fixing direction P of the magnetism is the sensitivity-axis direction of each magnetoresistance effect element 11a and the sensitivity-axis direction of the magnetism detection units 11, 12, 13, and 14. The magnetism of the magnetoresistance effect elements 11a in the magnetism detection unit 11 and the magnetism of the magnetoresistance effect elements 11a in the magnetism detection unit 14 are in the same fixing direction P, which is a downward direction in FIG. 2. The magnetism of the magnetoresistance effect elements 11a in the magnetism detection unit 12 and the magnetism of the magnetoresistance effect elements 11a in the magnetism detection unit 13 are in the same fixing direction P, which is an upward direction in the drawing.

In each magnetoresistance effect element 11a described above, magnetism F in the free magnetic layer is placed in a single magnetic domain state and aligned in the X direction by a bias magnetic field formed by using shape anisotropy and an antiferromagnetic layer. When an external magnetic field is supplied in a direction matching the sensitivity-axis direction (fixing direction P) in the magnetism detection units 11, 12, 13, and 14, the direction of the magnetism F aligned in the X direction in the free magnetic layer is inclined toward the Y direction. When the angle between the vector of the magnetism in the free magnetic layer and the fixing direction P of the magnetism becomes small, the electric resistance of the magnetoresistance effect element 11a is lowered. When the angle between the vector of the magnetism in the free magnetic layer and the fixing direction P of the magnetism becomes large, the electric resistance of the magnetoresistance effect element 11a is increased.

As indicated in the circuit diagram in FIG. 7, a power supply Vdd is connected to the wiring path 5, the wiring path 6 is grounded, and a constant voltage is applied to a full bridge circuit formed from the magnetism detection units 11, 12, 13, and 14. A midpoint voltage V1 is obtained from the wiring path 8, and a midpoint voltage V2 is obtained from the wiring path 7.

A lower insulative layer is formed on the surface of the magnetism detection units 11, 12, 13, and 14. As illustrated in FIG. 4A, the feedback coil 30 is formed on the surface of the lower insulative layer. In FIG. 1, a planar pattern of the feedback coil 30 is illustrated in FIG. 1. The feedback coil 30 is formed by spirally winding a plurality of coil conductors 35 clockwise from one land 31 toward another land 32. An opposing detection part 30a, which is part of the feedback coil 30, is placed above the magnetism detection units 11, 12, 13, and 14.

At the opposing detection part 30a, the plurality of coil conductors 35, which are spirally wound as the feedback coil 30, linearly extend in parallel to one another in the X direction. In FIG. 4, the shape of the cross-section of the feedback coil 30 at the opposing detection part 30a is illustrated. At the opposing detection part 30a, the plurality of coil conductors 35 are spaced at fixed intervals in the Y direction.

The coil conductor 35, which is a plated layer, is formed from gold that forms a low-resistance non-magnetic metal layer. However, the coil conductor 35 may be formed from another metal such as copper. As illustrated in FIG. 4B, the coil conductor 35 preferably has a rectangular cross-sectional shape in which the width W1 in the Y direction is longer than the height H1 in the Z direction. The width W1 is about 20 to 60 μm, and the height H1 is one-third the width W1 or less.

As illustrated in FIGS. 4A and 4B, the magnetoresistance effect elements 11a included in the magnetism detection unit 11 are arranged at a constant pitch in the Y direction. An opposing surface 35a forming the bottom surface of the coil conductor 35 is a longer edge of the cross-sectional shape. A plurality of magnetoresistance effect elements 11a oppose the opposing surface 35a of a single coil conductor 35 in the Z direction. In the embodiment illustrated in FIG. 4A, three magnetoresistance effect elements 11a oppose the opposing surface 35a.

In other magnetism detection units 12, 13, and 14 as well, three magnetoresistance effect elements 11a oppose the opposing surface 35a of a single coil conductor 35 in the same way.

The top of the opposing detection part 30a of the feedback coil 30 is covered with an upper insulating layer. The shield layer 3 is preferably formed on the upper shielding layer. The shield layer 3 is a plated layer formed from a magnetic metal material such as a nickel-iron (Ni—Fe) alloy.

As indicated in the circuit diagram in FIG. 7, the magnetism detection units 11, 12, 13, and 14 constitute a bridge circuit. The midpoint voltages V1 obtained from the wiring path 8 and the midpoint voltages V2 obtained from the wiring path 7 are supplied to a coil energization unit 15. The coil energization unit 15 has a differential amplification unit 15a and a compensation circuit 15b. The main component of the differential amplification unit 15a is an operational amplifier. When the midpoint voltages V1 and V2 are entered into the differential amplification unit 15a, the difference (V1−V2) between them is obtained as a detected voltage Vd. This detected voltage Vd is supplied to the compensation circuit 15b, in which a coil current Id, which is a compensation current, is created. The coil current Id is supplied to the feedback coil 30.

A single unit formed by integrating the differential amplification unit 15a and compensation circuit 15b together is sometimes referred to as a compensation-type differential amplification unit.

As illustrated in FIG. 7, the land 31 of the feedback coil 30 is connected to the compensation circuit 15b and the land 32 is connected to a current detection unit 17. The current detection unit 17 has a resistor 17a connected to the feedback coil 30 and a voltage detection unit 17b that detects a voltage applied to the resistor 17a.

Next, the operation of the equilibrium-type magnetic field detection device 1 will be described.

As illustrated in FIG. 7, a magnetic field H0 under measurement is induced by the current I0 under measurement flowing in the current path 40 in the X direction. The current I0 under measurement is an alternating current or a direct current. An instant will be assumed here at which the current I0 under measurement flows in the upward direction in FIG. 7 and flows in the backward direction in FIG. 4A. The direction of the magnetic field H0 under measurement at this instance is indicated by arrows in FIG. 4A and an arrow in FIG. 7. The Y-direction component of the magnetic field is applied to the magnetism detection units 11, 12, 13, and 14.

As illustrated in FIGS. 2 and 7, the fixing direction P of the magnetism in the fixed magnetic layers in the magnetism detection units 11 and 14 and the fixing direction P of the magnetism in the fixed magnetic layers in the magnetism detection units 12 and 13 are opposite to each other. When the magnetic field H0 under measurement in the direction indicated by an arrow in FIGS. 4A and 7 is supplied to the magnetism detection units 11, 12, 13, and 14, the resistance of each magnetoresistance effect element 11a is increased in the magnetism detection unit 11 and magnetism detection unit 14 and the resistance of each magnetoresistance effect element 11a is decreased in the magnetism detection unit 12 and magnetism detection unit 13. At that time, as the current I0 under measurement becomes large, the detected voltage Vd, which is an output from the differential amplification unit 15a, is increased.

The coil current Id is supplied from the compensation circuit 15b to the feedback coil 30, causing a cancel current Id1 to flow in the feedback coil 30. In the opposing detection part 30a, the current I0 under measurement and cancel current Id1 flow in opposite directions. In the magnetism detection units 11, 12, 13, and 14, the cancel current Id1 causes a cancel magnetic field Hd in a direction in which the magnetic field H0 under measurement is canceled.

When the magnetic field H0 under measurement induced by the current I0 under measurement is larger than the cancel magnetic field Hd, the midpoint voltages V1 obtained from the wiring path 8 is increased and the midpoint voltages V2 obtained from the wiring path 7 is lowered. Therefore, the detected voltage Vd, which is an output from the differential amplification unit 15a, is increased. At that time, in the compensation circuit 15b, the coil current Id, which increases the cancel magnetic field Hd to make the detected voltage Vd described above approach zero, is created. This coil current Id is supplied to the feedback coil 30. The magnetic field H0 under measurement and the cancel magnetic field Hd exerted on the magnetism detection units 11, 12, 13, and 14 are placed in an equilibrium state. When the detected voltage Vd falls to or below a predetermined value in this state, the coil current Id (cancel current Id1) flowing in the feedback coil 30 is detected by the current detection unit 17 illustrated in FIG. 7. The detected current is the measured current value of the current I0 under measurement.

In the equilibrium-type magnetic field detection device 1 described above, the shield layer 3 is preferably formed above the magnetism detection units 11, 12, 13, and 14 and the feedback coil 30. Since part of the magnetic field H0 under measurement induced by the current I0 under measurement is absorbed by the shield layer 3, the magnetic field HO under measurement to be supplied to the magnetism detection units 11, 12, 13, and 14 is reduced. As a result, it is possible to widen a range within which the current I0 under measurement changes until the magnetoresistance effect elements 11a in the magnetism detection units 11, 12, 13, and 14 are magnetically saturated, enabling a dynamic ranged to be widened.

At the opposing detection part 30a of the feedback coil 30, three magnetoresistance effect element 11a oppose the opposing surface 35a of a single coil conductor 35, as illustrated in FIGS. 4A and 4B.

Therefore, the magnetic field component exerted on each magnetoresistance effect element 11a in parallel to the sensitivity axis (fixing direction P of the magnetism) can be increased, so high linearity can be maintained in the detection outputs in the magnetism detection units 11, 12, 13, and 14. Furthermore, since the coil current Id needed to change the resistances of the magnetism detection units 11, 12, 13, and 14, that is, the cancel current Id1, becomes large, the detection sensitivity of the magnetism detection units 11, 12, 13, and 14 can be increased.

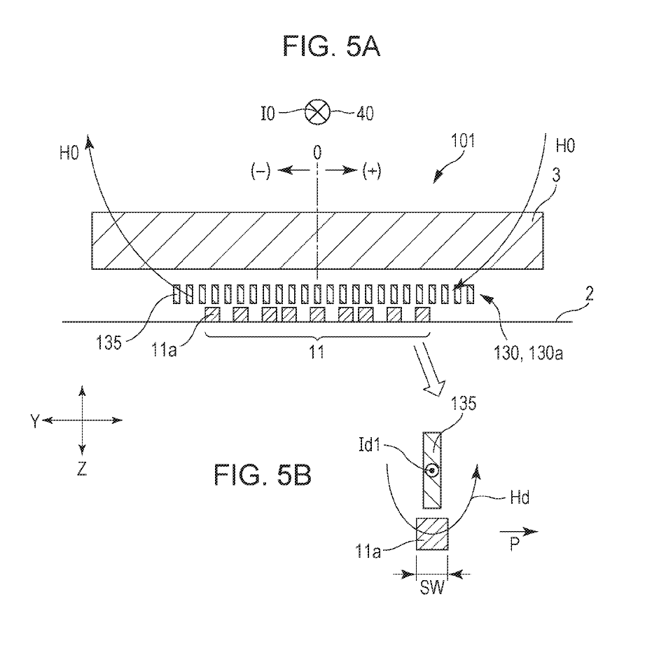

FIG. 5A is a cross-sectional view of an equilibrium-type magnetic field detection device 101 in a comparative example, the cross-sectional view in FIG. 5A being taken at the same position as the cross-sectional view in FIG. 4A.

The width SW of the magnetoresistance effect element 11a in the magnetism detection units 11, 12, 13, and 14 in the Y direction and the pitch at which the magnetoresistance effect elements 11a are arranged in the Y direction are the same between the equilibrium-type magnetic field detection device 1 in the embodiment illustrated in FIG. 4A and the equilibrium-type magnetic field detection device 101 in the comparative example illustrated in FIG. 5A.

In the comparative example in FIG. 5A, however, the Y-direction width of each coil conductor 135 of an opposing detection part 130a included in a feedback coil 130 is small, and coil conductors 135 and magnetoresistance effect elements 11a oppose vertically on a one-to-one basis. The Y-direction width is almost the same between the opposing detection part 30a of the feedback coil 30 in FIG. 4A and the opposing detection part 130a of the feedback coil 130 in FIG. 5A. Therefore, the number of windings of the coil conductors 135 of the feedback coil 130 in the comparative example in FIG. 5A is larger than the number of windings of the feedback coil 30 in the embodiment in FIG. 4A.

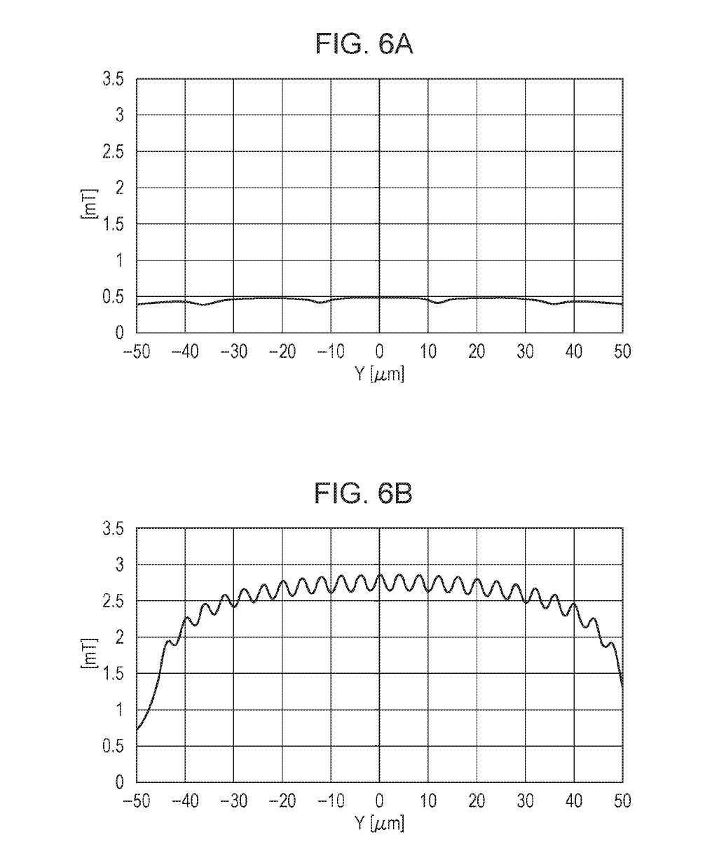

FIG. 6A illustrates measurement results for the Y-direction component of the cancel magnetic field Hd induced from individual coil conductors 35 constituting the feedback coil 30 in the embodiment illustrated in FIG. 4A, the measurement results having been obtained at a position 0.5 μm distant downward in FIG. 4A from the opposing surface 35a, which is the bottom surface of the coil conductor 35. FIG. 6B illustrates measurement results for the Y-direction component of the cancel magnetic field Hd induced from individual coil conductors 135 constituting the feedback coil 130 in the comparative example illustrated in FIG. 5A, the measurement results having been obtained at a position 0.5 μm distant downward in FIG. 5A from the bottom surface of the coil conductor 135.

In FIGS. 6A and 6B, the horizontal axis indicates Y-coordinate positions starting from point 0 in FIGS. 4A and 5A in the right direction (+) and left direction (−), and the vertical axis indicates the strength (mT) of the Y-direction component of the cancel magnetic field Hd.

The coil conductor 35 in the embodiment illustrated in FIG. 4B had a cross-sectional shape in which the width W1 in the Y direction is 22 μm and the height H1 in the Z direction is 5 μm. The coil conductor 135 in the comparative example illustrated in FIG. 5B had a cross-sectional shape in which the width in the Y direction is 2 μm and the height in the Z direction is 5 μm. In FIGS. 4B and 5B, the width SW of each magnetoresistance effect element 11a in the Y direction was 4 μm.

To induce the cancel magnetic field Hd illustrated in FIGS. 6A and 6B, a direct current of 10 mA was supplied to the feedback coil 30 in the embodiment and to the feedback coil 130 in the comparative example, as the coil current Id.

In the comparative example in FIG. 5A, the coil conductors 135 having a small width in the Y direction were arranged at a short pitch. At the height at which the magnetoresistance effect elements 11a were arranged, therefore, the Y-direction component of the cancel magnetic field Hd fluctuated at short intervals matching the pitch at which the coil conductors 135 were arranged, as illustrated in FIG. 6B. In the embodiment in FIG. 4A, however, the width of the each coil conductor 35 in the Y direction was large. Therefore, the Y-direction component of the cancel magnetic field Hd was easily exerted at the height at which the magnetoresistance effect elements 11a were arranged, as illustrated in FIG. 6A.

Furthermore, the amount of cancel current Id1 per width in the Y direction, that is, the current density in the Y direction was lower in the embodiment in FIG. 4A than in the comparative example in FIG. 5A.

Therefore, unlike the equilibrium-type magnetic field detection device 101 in the comparative example, the equilibrium-type magnetic field detection device 1 in the embodiment of the present invention has the following effects.

(1) In the comparative example, the rounding component of the cancel magnetic field Hd induced by each coil conductor 135 is exerted on the relevant magnetoresistance effect element 11a, as illustrated in FIG. 5B. Therefore, the Y-direction component of the cancel magnetic field Hd is strengthened at the central portion, in the width direction, of the magnetoresistance effect element 11a having the width SW. However, the Y-direction component of the cancel magnetic field Hd is weakened at both ends of the width SW. This reduces linearity in variations of the resistances of the magnetoresistance effect elements 11a, the variations being caused when the cancel current Id1 changes. When the coil current Id is an alternating current and the cancel magnetic field Hd is thereby an alternating magnetic field, the hysteresis of variations of the resistances of the magnetoresistance effect elements 11a becomes large.

In the embodiment, however, the Y-direction component of the cancel magnetic field Hd induced by a single coil conductor 35 having a large width in the Y direction is easily exerted on each of the relevant magnetoresistance effect elements 11a, as illustrated in FIG. 4B. In particular, the Y-direction component of the cancel magnetic field Hd is dominantly exerted on the magnetoresistance effect element 11a at the center of the three magnetoresistance effect elements 11a opposing the coil conductor 35. With the equilibrium-type magnetic field detection device 1 in the embodiment, therefore, the linearity of the detection outputs of the magnetism detection units 11, 12, 13, and 14 can be easily maintained, and hysteresis when the cancel magnetic field Hd is an alternating magnetic field can be reduced.

(2) When the coil current Id in the embodiment in FIG. 4A and the coil current Id in the comparative example in FIG. 5A have the same value, the cancel magnetic field Hd exerted on each magnetoresistance effect element 11a in the embodiment as illustrated in FIG. 6A is weaker than the cancel magnetic field Hd exerted on each magnetoresistance effect element 11a in the comparative example as illustrated in FIG. 6B.

Therefore, when the cancel magnetic field Hd large enough to cancel the magnetic field H0 under measurement to be detected by the magnetism detection units 11, 12, 13, and 14 is supplied to the magnetoresistance effect elements 11a, the coil current Id needed for this is larger in the embodiment illustrated in FIG. 4A than in the comparative example illustrated in FIG. 5A.

FIG. 11 indicates the strength of the magnetic field H0 under measurement on the horizontal axis and also indicates the coil current Id needed to cancel the magnetic field HO under measurement on the vertical axis. In the comparative example in FIG. 5A, the range within which the coil current Id needed to cancel the magnetic field H0 under measurement, which changes within a predetermined range, is increased or decreased is narrow as indicated by a straight line (ii) in FIG. 11. By comparison, in the embodiment in FIG. 4A, the range within which the coil current Id needed to cancel the magnetic field H0 under measurement, which changes within a predetermined range, is increased or decreased is wide as indicated by a straight line (i). This means that the equilibrium-type magnetic field detection device 1 in the embodiment has higher detection sensitivity than the equilibrium-type magnetic field detection device 101 in the comparative example.

Therefore, even if the magnetic field H0 under measurement is relatively weak, a detection output can be obtained at a high signal-to-noise (S/N) ratio.

(3) In the embodiment in FIG. 4A, the cross-sectional area of each coil conductor 35 can be enlarged, so the resistance of the feedback coil 30 can be reduced. Since the number of windings of the feedback coil 30 can also be reduced, its impedance can be reduced by reducing its inductance. Accordingly, the equilibrium-type magnetic field detection device 1 is also superior in the detection of the current I0 under measurement at a high frequency and power consumption can also be reduced.

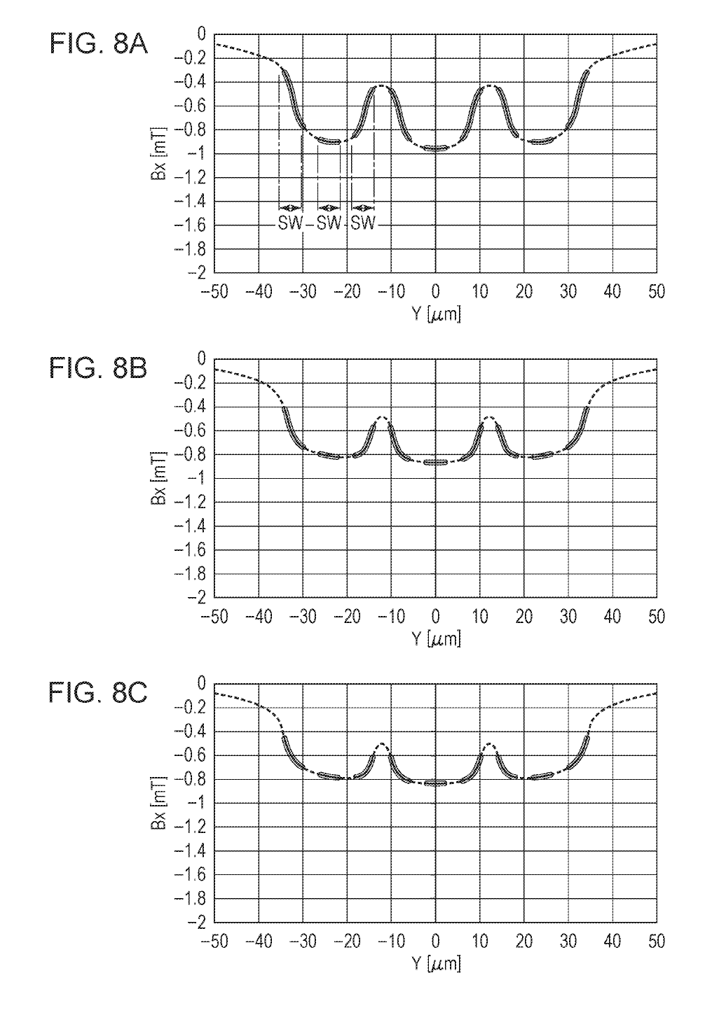

Next, relationships will be described between variations in the width W1 of the coil conductor 35 and variations in the Y-direction component of the cancel magnetic field Hd exerted on the magnetoresistance effect element 11a, with reference to FIGS. 8A, 8B, and 8C to FIGS. 10A, 10B, and 10C.

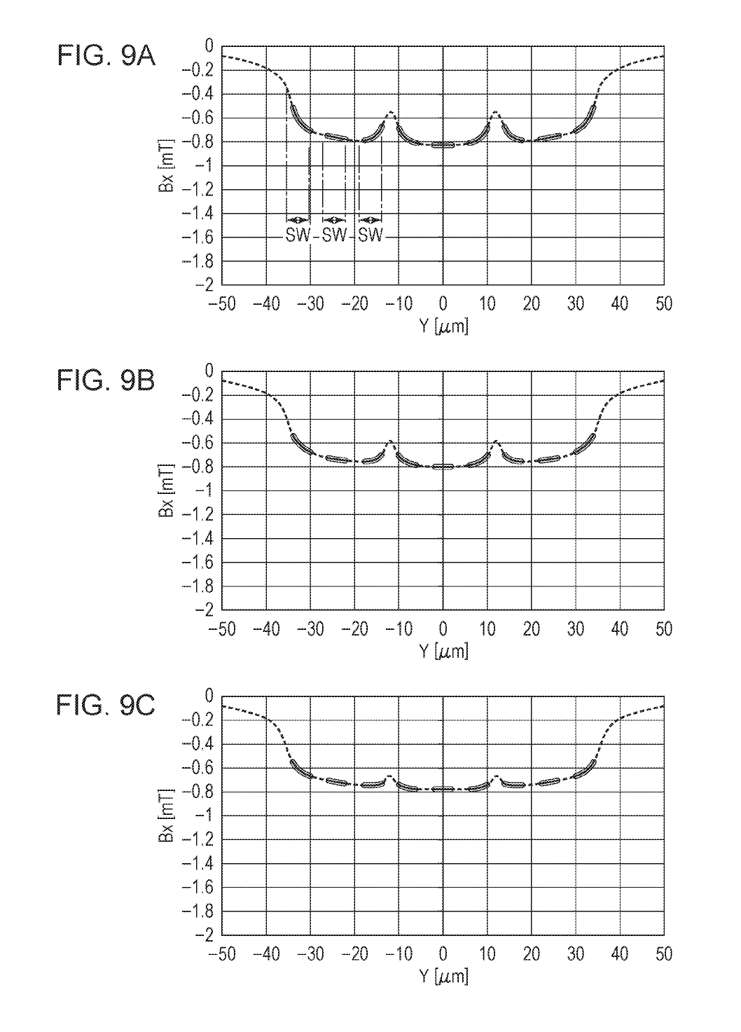

In FIGS. 8A, 8B, and 8C and FIGS. 9A, 9B, and 9C, the horizontal axis indicates Y-direction coordinate positions indicated in FIG. 4A and the vertical axis indicates the magnitude of the Y-direction component of the cancel magnetic field Hd at a position 0.5 μm distant downward in the Z direction from the opposing surface 35a of the coil conductor 35. The direction of the cancel magnetic field Hd is opposite to the direction in measurement in FIG. 6A, so the signs of the magnitude of the Y-direction cancel magnetic field Hd in FIGS. 8A, 8B, and 8C and FIGS. 9A, 9B, and 9C are reverse to the signs in FIG. 4A.

The width SW of the magnetoresistance effect element 11a is 4 μm. The height H1 of the coil conductor 35 is 2 μm.

In FIGS. 8A, 8B, and 8C and FIGS. 9A, 9B, and 9C, the curve of variations in the magnitude of the Y-direction component of the cancel magnetic field Hd at individual positions in the Y direction is indicated by a broken line. Of the curve, indicated by a broken line, of the variations, a range in which the coil conductor 35 opposes an individual magnetoresistance effect element 11a (the range of the width SW) is indicated by a triple line.

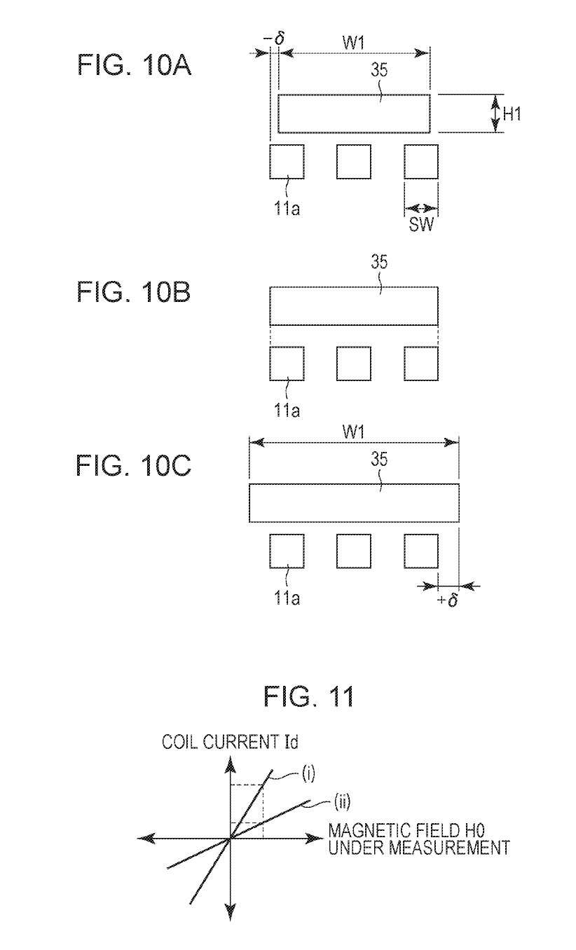

Conditions that yield the measurement result in FIG. 8A are that the width W1 of the coil conductor 35 illustrated in FIG. 10A is 16 μm and a dimension −δ by which the magnetoresistance effect elements 11a positioned at both ends in the Y direction protrude from the coil conductor 35 is −2.0 μm.

Conditions that yield the measurement result in FIG. 8B are that the width W1 of the coil conductor 35 is 19 μm and the dimension −δ by which the magnetoresistance effect elements 11a positioned at both ends in the Y direction protrude from the coil conductor 35 is −0.5 μm.

Conditions that yield the measurement result in FIG. 8C are that the width W1 of the coil conductor 35 is 20 μm and an end, in the Y direction, of each of the magnetoresistance effect elements 11a positioned at both ends in the Y direction is aligned with the relevant end of the coil conductor 35 in the Y direction, as illustrated n FIG. 10B.

Conditions that yield the measurement result in FIG. 9A are that the width W1 of the coil conductor 35 illustrated in FIG. 10C is 21 μm and the coil conductor 35 protrudes by +δ (=0.5 μm) from each of the magnetoresistance effect elements 11a positioned at both ends in the Y direction.

Conditions that yield the measurement result in FIG. 9B are that the width W1 of the coil conductor 35 is 22 μm and the coil conductor 35 protrudes by +5 (=1.0 μm) from each of the magnetoresistance effect elements 11a positioned at both ends in the Y direction.

Conditions that yield the measurement result in FIG. 9C are that the width W1 of the coil conductor 35 is 23 μm and the coil conductor 35 protrudes by +δ (=1.5 μm) from each of the magnetoresistance effect elements 11a positioned at both ends in the Y direction.

According to the results in FIGS. 8A, 8B, and 8C and FIGS. 9A, 9B, and 9C, of the cancel magnetic field Hd exerted on the magnetoresistance effect element 11a at the center of the three magnetoresistance effect elements 11a opposing a single coil conductor 35, the Y-direction component is strong under all conditions described above. To make the Y-direction component of the cancel magnetic field Hd exerted on the magnetoresistance effect elements 11a positioned at both ends in the Y direction, it is preferable for these magnetoresistance effect elements 11a not to protrude from the coil conductor 35 in the sensitivity-axis direction as illustrated in FIG. 8C and FIG. 10B. It is further preferable for both ends of the coil conductor 35 in the Y direction to protrude from the magnetoresistance effect elements 11a at both ends in the Y direction, as illustrated in FIGS. 9A, 9B, and 9C and FIG. 10C.

There is no limitation on the number of magnetoresistance effect elements 11a opposing a single coil conductor 35 if the number is 2 or larger. However, that number is preferably an odd number such as 3. When an odd number of magnetoresistance effect elements 11a oppose a single coil conductor 35, the magnetoresistance effect element 11a at the center of them opposes the central portion of the coil conductor 35. Then, the Y-direction magnetic field component is dominantly exerted on the magnetoresistance effect element 11a at the center. Therefore, the linearity of detection outputs can be easily secured, and hysteresis can be suppressed.

What is claimed is:

1. An equilibrium-type magnetic field detection device comprising:
a feedback coil formed by winding at least one coil conductor around a flat surface;
at least one magnetism detection unit that has a plurality of magnetoresistance effect elements, each of which is formed in an elongated-strip shape along the at least one coil conductor;
a coil energization unit that supplies, to the at least coil conductor, a current that induces a magnetic field according to a detection output obtained when the at least magnetism detection unit detects a magnetic field under measurement, the magnetic field being directed so as to cancel the magnetic field under measurement; and
a current detection unit that detects an amount of current that flows in the at least coil conductor; wherein
in one of the at least one magnetism detection unit, the plurality of magnetoresistance effect elements are arranged in parallel and are connected in series, detection axes of the plurality of magnetoresistance effect elements being disposed in the same orientation, and
a plurality of magnetoresistance effect elements included in one of the at least one magnetism detection unit oppose one of the at least one coil conductor.

2. The equilibrium-type magnetic field detection device according to claim 1, wherein the plurality of the magnetoresistance effect elements preferably oppose a portion of the at least one coil conductor, the portion linearly extending.

3. The equilibrium-type magnetic field detection device according to claim 1, wherein each of the at least one coil conductor has a rectangular cross-sectional shape in which a dimension in a height direction is shorter than a dimension in a width direction, the magnetoresistance effect elements opposing a long side of the cross-sectional shape, the long side extending in the width direction of the cross-sectional shape.

4. The equilibrium-type magnetic field detection device according to claim 1, wherein the plurality of the magnetoresistance effect elements do not protrude from the at least one coil conductor in the width direction.

5. The equilibrium-type magnetic field detection device according to claim 1, further comprising a magnetic shield layer that reduces the magnetic field under measurement, which extends to the magnetoresistance effect elements.

6. The equilibrium-type magnetic field detection device according to claim 1, further comprising a current path, wherein
the magnetic field under measurement induced by the current path is supplied to the magnetoresistance effect elements.
